(19) United States
(12) Patent Application Publication
(10) Pub. No.: US 2026/0196279 A1
(43) Pub. Date: Jul. 9, 2026

(54) SEMICONDUCTOR DEVICES, PROGRAMMING METHODS THEREOF, AND MEMORY SYSTEMS

(71) Applicant: Yangtze Memory Technologies Co., LTD, Wuhan (CN)

(72) Inventors: Ke Ke, Wuhan (CN); Zhipeng Dong, Wuhan (CN); JinChi Han, Wuhan (CN)

(21) Appl. No.: 19/251,417

(22) Filed: Jun. 26, 2025

(30) Foreign Application Priority Data
Jan. 3, 2025 (CN) 202510014782.2

(51) Int. Cl. G11C 16/34; G11C 5/06; G11C 16/04; G11C 16/20

(52) U.S. Cl. CPC G11C 16/3431; G11C 5/063; G11C 16/0483; G11C 16/20

(57) ABSTRACT

The present disclosure provides a semiconductor device, a program method thereof and a memory system. The semiconductor device including a memory cell array, word lines coupled with the memory cell array, and a peripheral circuit coupled with the word lines, wherein the peripheral circuit is configured to: perform a programming operation on a plurality of memory cells coupled with a selected word line, such that threshold voltages of the plurality of memory cells form a plurality of initial threshold voltage distributions corresponding to a plurality of program states, wherein memory cells forming the same initial threshold voltage distribution constitute a subset; and perform a reprogramming operation on the plurality of memory cells.

### CROSS-REFERENCE TO RELATED APPLICATIONS

This application claims priority to and the benefit of Chinese Patent Application 202510014782.2, filed on Jan. 3, 2025, which is hereby incorporated by reference in its entirety.

### TECHNICAL FIELD

The present disclosure relates to the field of semiconductor technologies, and in particular, to semiconductor devices, programming methods thereof, and memory systems.

### BACKGROUND

Since the introduction of NAND memory, whether in the 2D or 3D era, the core driving force behind the development of NAND technology has been to improve performance, extend lifespan, enhance reliability, increase storage density, and reduce the cost per memory cell. One important way to achieve increased storage density and reduced cost per memory cell is logical scaling. The logical scaling refers to raising storage density with bit scaling of memory cells. The logical scaling may sacrifice performance while providing storage density.

### BRIEF DESCRIPTION OF DRAWINGS

FIG. 1 is a schematic diagram of an example system provided by an example of the present disclosure.

FIG. 2a is a schematic diagram of a memory card provided by an example of the present disclosure.

FIG. 2b is a schematic diagram of an SSD provided by an example of the present disclosure.

FIG. 3 is a schematic diagram of a memory comprising a peripheral circuit provided by an example of the present disclosure.

FIG. 4 is a schematic diagram of a memory cell array comprising a NAND memory string provided by an example of the present disclosure.

FIG. 5 is a schematic diagram of a change of a bit of a memory cell provided by an example of the present disclosure.

FIG. 6 is a schematic diagram of a peripheral circuit provided by an example of the present disclosure.

FIG. 7 is a schematic diagram of threshold voltage distributions of memory cells in a programming operation and a reprogramming operation provided by an example of the present disclosure.

FIG. 8 is a schematic diagram of threshold voltage distributions before and after a reprogramming operation is performed on any subset provided by an example of the present disclosure.

FIG. 9 is a first schematic diagram of a reprogramming operation provided by an example of the present disclosure.

FIG. 10 is a second schematic diagram of a reprogramming operation provided by an example of the present disclosure.

FIG. 11 is a schematic diagram of a preset program pulse on a selected word line in a program stage provided by an example of the present disclosure.

FIG. 12 is a third schematic diagram of a reprogramming operation provided by an example of the present disclosure.

FIG. 13 is a schematic diagram of a programming scheme provided by an example of the present disclosure.

FIG. 14 is a first flowchart of a programming scheme provided by an example of the present disclosure.

FIG. 15 is a second flowchart of a programming scheme provided by an example of the present disclosure.

FIG. 16 is a schematic diagram of E0, Esum, and E0+Esum of two programming schemes provided by an example of the present disclosure.

FIG. 17 is a schematic flowchart of a programming method provided by an example of the present disclosure.

### DETAILED DESCRIPTION

Example aspects disclosed in the present disclosure will be described in more detail below with reference to the drawings. Although example aspects of the present disclosure are shown in the drawings, it is to be understood that the present disclosure may be implemented in various forms and should not be limited to the detailed description set forth herein. Rather, these aspects are provided such that the present disclosure can be more thoroughly understood and the scope disclosed in the present disclosure can be fully conveyed to those skilled in the art.

In the following description, numerous specific details are given in order to provide a more thorough understanding of the present disclosure. It will be apparent to those skilled in the art, however, that the present disclosure may be practiced without one or more of these details. In other examples, to avoid confusion with the present disclosure, some technical features known in the art are not described; that is, not all features of the actual examples are described herein, and well-known functions and structures are not described in detail.

In the drawings, like reference numerals refer to like elements throughout.

It should be understood that spatial relation terms such as “beneath,” “below,” “lower,” “under,” “above,” “upper,” etc., may be used herein for ease of description to describe the relationship between one element or feature and other elements or features shown in the drawings. It should be appreciated that in addition to the orientations shown in the drawings, the spatial relation term intent to also include different orientations of the devices in use and operation. For example, if the devices in the drawings are flipped, then described as “below” or “under” or “beneath” other elements or features will be oriented “on” other elements or features. Thus, the example terms “below” and “under” may include both upper and lower orientations. The devices may be additionally oriented (rotated 90 degrees or other orientations) and the spatial description terminology used herein is interpreted accordingly.

A term used herein is just for the purpose of describing a particular example and is not to be considered as limitation of the present disclosure. As used herein, “a,” “an” and “said/the” in the singular forms are intended to include the plural forms as well, unless the context clearly indicates otherwise. It should also be understood that at least one of the terms “consists of” or “comprising,” when used in this specification, identify the presence of at least one of stated features, integers, steps, operations, elements or components, but do not exclude the presence or addition of at least one of one or more other features, integers, steps, operations, elements, components or groups. As used herein, the term “at least one of” includes any and all combinations of the related listed items.

Increasing storage density to reduce the cost per memory cell has always been the direction and driving force of NAND memory development, while achieving increased storage density and reduced cost per memory cell, mainly relying on capacity expansion of NAND memory. An important way of capacity expansion is logical scaling. The logical scaling refers to raising storage density with bit expansion of memory cells. At present, NAND products have experienced the development of SLC→MLC→TLC→QLC. The present disclosure provides a concept of 4.5 bit/cell, where 4.5 bit/cell refers to a memory cell storing 4.5 bits, which is between QLC and PLC. For a 4.5 bit/cell product, one memory cell needs to have one of 24 states. With more states of the memory cell are divided, the probability of the error occurring when writing the data or reading the data is increased, resulting in a decrease in the reliability of the memory cell. How to improve reliability is one of the key difficulties in achieving mass production of 4.5 bit/cell products.

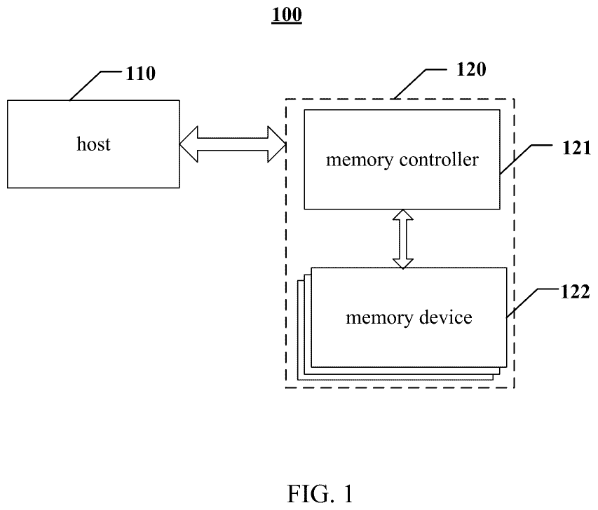

FIG. 1 is a block diagram of an example system comprising a memory device provided by an example of the present disclosure. The example system 100 may include a host 110 and a memory system 120. The example system 100 may include, but is not limited to, a mobile phone, a desktop computer, a laptop computer, a tablet computer, a vehicle computer, a game console, a printer, a positioning device, a wearable electronic device, a smart sensor, a Virtual Reality (VR) device, an Augmented Reality (AR) device, or any other suitable electronic device having a memory device 122 therein; the host 110 may be a processor (e.g., a Central Processing Unit (CPU) or a System on Chip (SoC) (e.g., an Application Process (AP)) of the electronic device.

In an example of the present disclosure, the host 110 may be configured to send data to or receive data from the memory system 120. Here, the memory system 120 may include a memory controller 121 and one or more memory devices 122. The memory device 122 may include, but is not limited to, a NAND Flash Memory, a Vertical NAND Flash Memory, a NOR Flash Memory, a Dynamic Random Access Memory (DRAM), a Ferroelectric Random Access Memory (FRAM), a Magnetoresistive Random Access Memory (MRAM), a Phase Change Random Access Memory (PCRAM), a Resistive Random Access Memory (RRAM), a Nano Random Access Memory (NRAM), or the like.

In an example of the present disclosure, a Memory Controller 121 may be coupled to the memory device 122 and the host 110 and configured to control the memory device 122. For example, the memory controller 121 may be designed to operate in a low duty cycle environment, such as a Secure Digital (SD) card, a Compact Flash (CF) card, a Universal Serial Bus (USB) flash drive, or other medium for use in electronic devices such as personal computers, digital cameras, mobile phones, and the like. In some examples, the memory controller 121 may also be designed to operate in a high duty cycle environment, such as a Solid State Disk (SSD) or an embedded Multi-Media Card (eMMC), and the SSD or eMMC may be used as a data storage for a mobile device such as a smartphone, a tablet computer, and a laptop computer, etc., and an enterprise memory array.

Further, the memory controller 121 may manage data in the memory device 122 and communicate with the host. The memory controller 121 may be configured to control operations of the memory device 122, such as read, erase, and program; may also be configured to manage various functions regarding data stored in or to be stored in the memory device 122, comprising, but not limited to, bad block management, garbage collection, logical-to-physical address translation, wear leveling, etc. ; and may also be configured to process Error Checking and Correction (ECC) regarding data read from or written into the memory device 122. Furthermore, the memory controller 121 may also perform any other suitable function, such as formatting the memory device 122, or communicating with an external device (e.g., host 110 in FIG. 1) according to a particular communication protocol. For example, the memory controller 121 may communicate with an external host through at least one of various interface protocols, such as a USB protocol, an MMC protocol, a Peripheral Component Interconnect (PCI) protocol, a Peripheral Component Interconnect Express (PCI-E) protocol, an Advanced Technology Attachment (ATA) protocol, a serial ATA protocol, a parallel ATA protocol, a Small Computer System Interface (SCSI) protocol, an Enhanced Small Disk Interface (ESDI) protocol, an Integrated Development Equipment (IDE) protocol, a Firewire protocol, or the like.

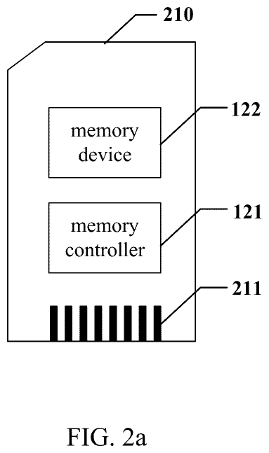

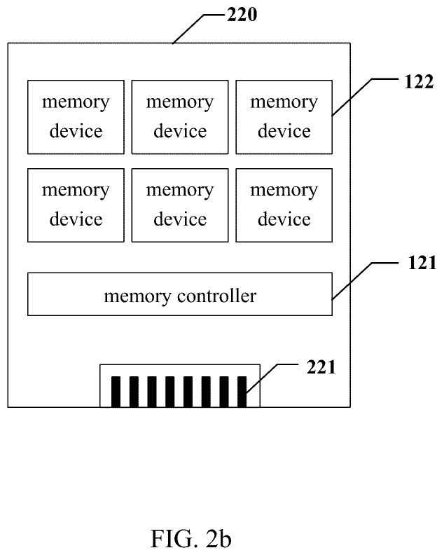

In an example of the present disclosure, the memory controller 121 and the one or more memory devices 122 may be integrated into various types of storage devices, for example, included in the same package (e.g., Universal Flash Storage (UFS) package or eMMC package). That is, the memory system 120 may be implemented and packaged into different types of terminal electronics. As shown in FIG. 2a, the memory controller 121 and the single memory device 122 may be integrated together to form the memory card 210. The memory card 210 may include a PC card (Personal Computer Memory Card International Association), a CF card, a Smart Media (SM) card, a memory stick, a multimedia card (MMC (Multi-Media Card), an RS-MMC (Reduced Size MMC), an MMCmicro), an SD card (SD, miniSD, microSD, Secure Digital High Capacity (SDHC)), UFS, and the like. The memory card 210 may also include a memory card connector 211 that couples the memory card 210 with a host (e.g., host 110 in FIG. 1). In another example as shown in FIG. 2b, the memory controller 121 and the plurality of memory devices 122 may be integrated together to form the SSD 220. SSD 220 may also include an SSD connector 221 that couples SSD 220 with a host (e.g., host 110 in FIG. 1). In some aspects, at least one of the storage capacity or operating speed of the SSD 220 is greater than at least one of the storage capacity or the operating speed of the memory card 210.

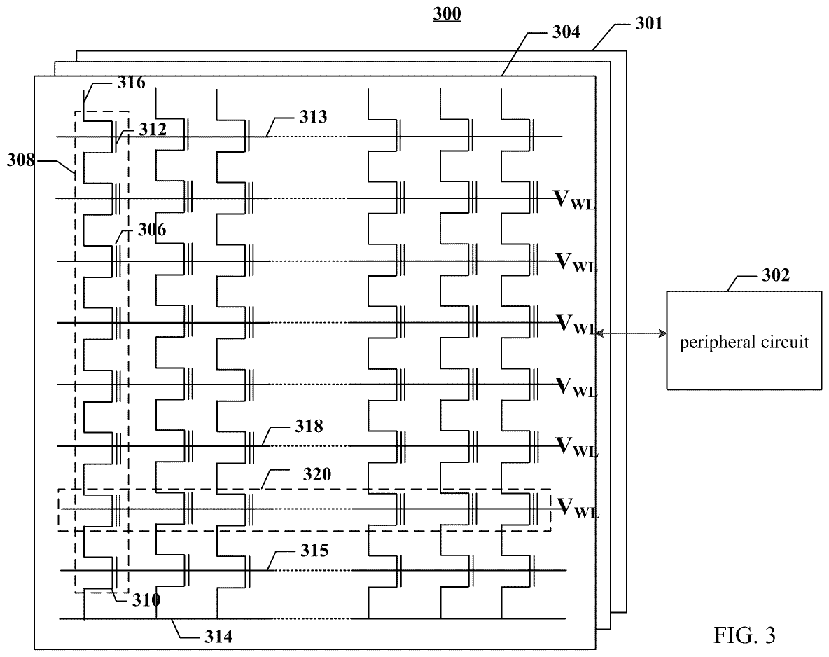

It should be noted that the memory device related to an example of the present disclosure may be a semiconductor memory, which is a solid state electronic device for storing data information made by a semiconductor integrated circuit process. FIG. 3 is a schematic diagram of a memory device comprising a peripheral circuit provided by an example of the present disclosure, where the memory device 300 may be the memory device 122 in FIG. 1 to FIG. 2b. As shown in FIG. 3, the memory device 300 may include a memory cell array 301 and a peripheral circuit 302 coupled to the memory cell array 301. Here, the memory cell array may be an array of NAND flash memory cells, where the memory cells are disposed in the form of an array of NAND memory strings 308, each extending vertically above the substrate. In some examples, each NAND memory string 308 may include a plurality of memory cells 306 coupled in series and stacked vertically. Each memory cell 306 may maintain a continuous analog value, such as a voltage or charge, depending on the number of electrons captured within the memory cell region. In addition, each memory cell 306 in the above memory cell array 301 may be a floating gate type of memory cell comprising a floating gate transistor, or a charge trapping type of memory cell comprising a charge trapping transistor.

As shown in FIG. 3, each NAND memory string 308 may include a source select transistor 310 at its source terminal and a drain select transistor 312 at its drain terminal. The source select transistor may also be referred to as a lower select transistor, and the drain select transistor may also be referred to as an upper select transistor. The source select transistor 310 and the drain select transistor 312 may be configured to activate the selected NAND memory string 308 (column of the array) during read and programming operations.

In some aspects, the sources of the NAND memory strings 308 in the same block 304 are coupled through the same source line (SL) 314 (e.g., a common source line). In other words, according to some aspects, all NAND memory strings 308 in the same block 304 have an array common source (ACS). According to some aspects, the drain select transistor 312 of each NAND memory string 308 is coupled to a respective bit line 316 from which data may be read or written via an output bus (not shown).

In some examples, each NAND memory string 308 is configured to be at least one of: selected or deselected by applying a select voltage (e.g., higher than a threshold voltage with a drain select transistor 312) or a deselect voltage (e.g., 0V) to a gate of a respective drain select transistor 312 via one or more drain select gate lines (DSG lines) 313; or selected or deselected by applying a select voltage (e.g., higher than a threshold voltage with a source select transistor 310) or a deselect voltage (e.g., 0V) to a gate of a respective source select transistor 310 via one or more source select gate lines 315. The NAND memory string 308 may thus be distinguished into a selected NAND memory string or a non-selected NAND memory string. The select voltage may also be referred to as a control turn-on voltage for turning on a corresponding transistor, and the deselect voltage may also be referred to as a control turn-off voltage for turning off a corresponding transistor.

As shown in FIG. 3, the NAND memory string 308 may be organized into a plurality of blocks 304, each of which may have a common source line 314 (e.g., coupled to ground). In some examples, each block 304 is a basic data unit for an erase operation, e.g., all memory cells 306 on the same block 304 are erased simultaneously. To erase the memory cells 306 in the selected block, the source lines 314 coupled to the selected block and non-selected blocks in the same plane as the selected block may be biased with erase voltages (Vers), such as a high positive voltage (e.g., 20V or higher). It should be understood that in some examples, an erase operation can be performed at a half-block level, a quarter-block level, or a level having any suitable number of blocks or fractions of a block.

Memory cells 306 of adjacent NAND memory strings 308 may be coupled by word lines 318 that select which row of memory cells 306 is affected by reading and programming operations. In some examples, each word line 318 is coupled to a page 320. Each word line 318 may include a plurality of control gates (gate electrodes) at each memory cell 306 in a respective page 320 and a gate line coupled to the control gate.

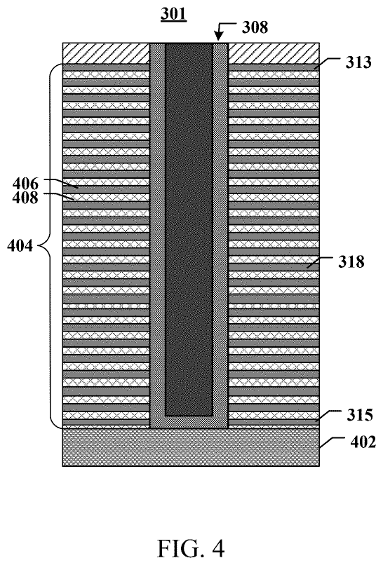

FIG. 4 is a schematic diagram of a memory cell array comprising a NAND memory string provided by an example of the present disclosure. As shown in FIG. 4, a NAND memory string 308 may extend vertically through the memory stack layer 404 over the substrate 402. The substrate 402 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

The memory stack layer 404 may include alternating gate conductive layers 406 and dielectric layers 408, where the number of pairs of gate conductive layers 406 and dielectric layers 408 may determine the number of memory cells 306 in the memory cell array 301. The gate conductive layer 406 may include a conductive material comprising, but not limited to, tungsten (W), cobalt (Co), copper (Cu), aluminum (Al), polysilicon, doped silicon, silicide, or any combination thereof. In some aspects, each gate conductive layer 406 includes a metal layer, such as a tungsten layer. In some aspects, each gate conductive layer 406 includes a doped polysilicon layer. The gate conductive layer 406 may extend laterally at the top of the memory stack layer 404 as the drain select gate line 313, extend laterally at the bottom of the memory stack layer 404 as the source select gate line 315, or extend laterally between the drain select gate line 313 and the source select gate line 315 as the word line 318. It should be understood that although one source select gate line (SSG line) 315 and one drain select gate line (DSG line) 313 are shown in FIG. 3, the number of source select gate lines 315 and the number of drain select gate lines 313 (and the number of source select transistors 310 and drain select transistors 312 coupled to the source select gate line 315 and drain select gate line 313, respectively) may vary in other examples.

As shown in FIG. 4, the NAND memory string 308 includes a channel structure that extends vertically through the memory stack layer 404. In some aspects, the channel structure includes a channel hole filled with a semiconductor material (e.g., as a semiconductor channel) and a dielectric material (e.g., as a memory film). In some aspects, the semiconductor channel includes silicon, e.g., polysilicon. In some aspects, the memory film is a composite dielectric layer comprising a tunneling layer, a storage layer (also referred to as a “charge trapping layer”), and a blocking layer. Channel structure can have a cylinder shape (e.g., a pillar shape). According to some aspects, the semiconductor channel, tunneling layer, storage layer, and blocking layer are arranged radially from the center toward the outer surface of the pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO). It should be understood that the structure of the channel structure depicted in FIG. 4 is just for illustrative purposes and may vary in other examples. It should be understood that although not shown in FIG. 4, additional components of the memory cell array 301 may also be formed comprising, but not limited to, gate line slit/source contacts, local contacts, interconnect layers, and the like.

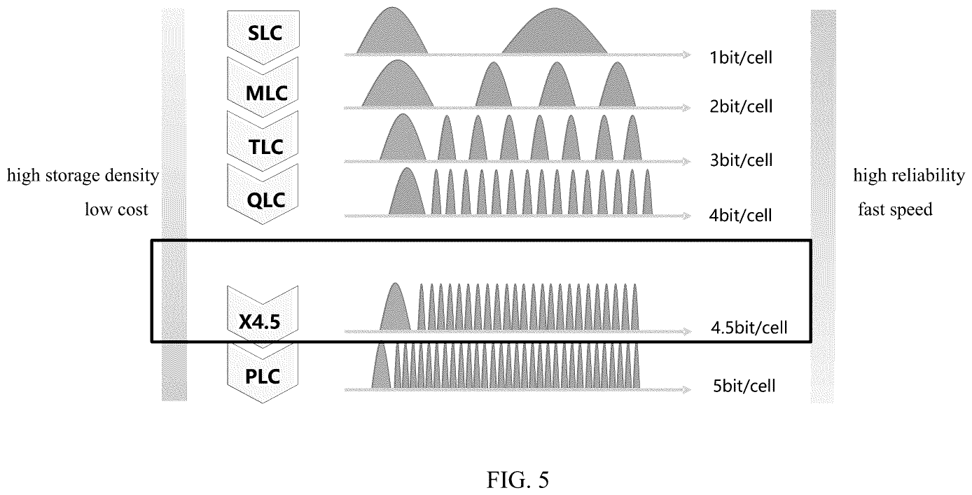

FIG. 5 is a schematic diagram of the development of bits of a memory cell provided by an example of the present disclosure. In some examples, a memory cell (e.g., memory cell 306 in FIG. 3) may be a Single Level Cell (SLC), which have two possible memory states and thus may store one bit of data. For example, the first memory state “0” may correspond to a first threshold voltage distribution, and the second memory state “1” may correspond to a second threshold voltage distribution. In other examples, the memory cell may be a multi-level memory cell capable of storing more than a single bit of data in more than four memory states. For example, the memory cell may store two bits of data in four memory states, referred to as a Two Level Cell or a Multi Level Cell (MLC). The memory cell may also store three bits of data in eight memory states, referred to as Triple Level Cell (TLC). The memory cell may also store four bits of data in sixteen states, referred to as Quad Level Cells (QLCs). Alternatively, the memory cell may also store five bits of data in thirty-two states, referred to as Penta Level Cell (PLC).

The division of the states of the memory cell may be understood as dividing the number of electrons in the storage layer (for example, the storage layer 424 in FIG. 4), taking the MLC as an example, for example, less than 10 electrons is determined as P1 state, 11 to 20 electrons is determined as P2 state, 21 to 30 electrons is determined as P3 state, and more than 30 electrons is determined as P4 state. The P1 state through the P4 state are four states corresponding to the MLC in FIG. 5. As shown in FIG. 5, as the number of bits stored in the memory cell increases, the data stored in the single memory cell becomes more and more, such that the storage density is increased and the cost per memory cell is reduced. However, at the same time, the division of the electrons in one memory cell is finer, so the number of electrons entering the memory layer is controlled to be finer when the write operation is performed, so the write time is extended. Similarly, more read voltages are required to read when reading is performed, and the read time may be extended such that the read speed is reduced. Moreover, as shown in FIG. 5, the distance between the threshold voltage distributions of adjacent states becomes smaller and smaller, such that the read margin is reduced, and the probability that errors occur when reading the data is increased, causing the reliability of the memory cell is reduced. Therefore, in term of performance, from the PLC to the SLC, the reliability gradually deteriorates and the read/write speed gradually decreases.

4.5 bit/cell, also referred to as X 4.5, is between QLC and PLC. In the 4.5 bit/cell products, the memory cell can store 4.5 bits of data in 24 states, and compared with the QLC that requires 32 states, there are less states, and thus the reliability is higher, the process difficulty is lower relative to QLC, and the implementability is improved. Compared with the QLC, one memory cell can store more data, so the storage density is larger and the cost is lower. In summary, storing 4.5 bits of data in a single memory cell is a feasible solution currently meeting the application of High Density Data (HDD).

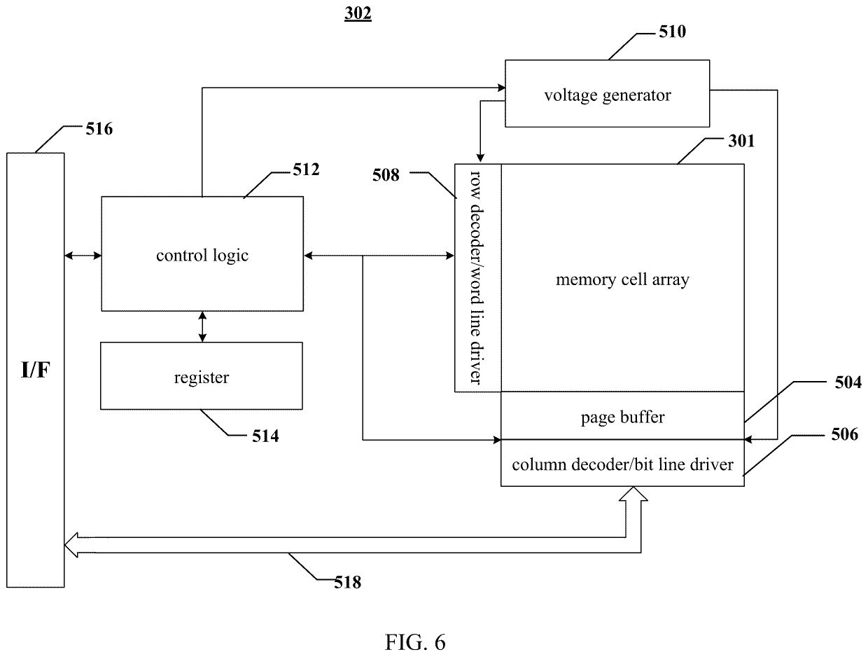

Referring back to FIG. 3, the peripheral circuit 302 may be coupled to the memory cell array 301 through bit lines 316, word lines 318, source lines 314, source select gate lines 315, and drain select gate lines 313. The peripheral circuit 302 may include any suitable analog, digital, and mixed signal circuit for implementing the write and read operations of the memory cell array 301 by applying at least one of voltage signal or current signal to each of the target memory cells 306 and sensing at least one of voltage signal or current signal from each of the target memory cells 306 via bit lines 316, word lines 318, source lines 314, source select gate lines 315, and drain select gate lines 313. The peripheral circuit 302 may include various types of peripheral circuit formed using metal-oxide-semiconductor (MOS) technology. For example, FIG. 6 is a schematic diagram of a peripheral circuit 302 comprising a page buffer 504, a column decoder/BL driver 506, a row decoder/WL driver 508, a voltage generator 510, a control logic 512, a register 514, an interface (I/F) 516, and a data bus 518 provided by an example of the present disclosure. It should be understood that in some examples, additional peripheral circuits not shown in FIG. 6 may also be included.

The page buffer 504 may be configured to read data from and program (write) data to the memory cell array 301 according to control signals from the control logic 512. In one example, the page buffer 504 may store a page of program data (write data) to be programmed into one page 320 of the memory cell array 301. In another example, the page buffer 504 may perform a program verify operation to ensure that the data has been properly programmed into the memory cells 306 coupled to the selected word line 318. In yet another example, the page buffer 504 may also sense a low power signal from the bit line 316 representing a data bit stored in the memory cell 306, and amplify the small voltage swing to an identifiable logic level in a read operation.

The column decoder/BL driver 506 may be configured to be controlled by control logic 512 and select one or more NAND memory strings 308 by applying a bit line voltage generated from voltage generator 510.

The row decoder/word line driver 508 may be configured to be controlled by the control logic 512 and select/deselect the block 304 of the memory cell array 301 and select/deselect the word line 318 in the block 304 according to the control signal generated by the control logic. The row decoder/WL driver 508 may also be configured to drive the word lines 318 using different word line voltages generated from the voltage generator 510. In some examples, the row decoder/WL driver 508 may also select/deselect the source select gate line 315 and the drain select gate line 313. The row decoder/WL driver 508 is configured to at least one of: drive the source select gate line 315 using a different SSG line voltage generated from the voltage generator 510 or to drive the drain select gate line 313 using a different DSG line voltage generated from the voltage generator 510.

The voltage generator 510 may be configured to be controlled by the control logic 512 and generate various word line voltages (e.g., read voltages, program voltages, pass voltages, verify voltages, etc.), bit line voltages, ground voltages, various SSG line voltages (e.g., select voltages, deselect voltages), and various DSG line voltages (e.g., select voltages, deselect voltages) to be supplied to the memory cell array 301.

Control logic 512 may be coupled to each peripheral circuit portion described above and configured to control operation of each peripheral circuit portion. Registers 514 may be coupled to control logic 512 and include status registers, command registers, and address registers to store status information, command operation code, and command addresses for controlling operation of the peripheral circuit. In some aspects, control logic 512 may receive program commands issued by a memory controller (e.g., memory controller 121 in FIG. 1) and send control signals to various peripheral circuit portions, such as row decoder/word line driver 508, column decoder/bit line driver 506, and voltage generator 510, to perform programming operations on source select transistors coupled to the source select gate lines.

Interface 516 may be coupled to control logic 512 and act as a control buffer to buffer control commands (e.g., program commands) received from a memory controller or host and relay them to control logic 512, and buffer status information received from control logic 512 and relay them to a memory controller or host. The interface 516 may also be coupled to the column decoder/bit line driver 506 via a data bus 518 and act as a data input/output (I/O) interface and a data buffer to buffer data and relay them to the memory cell array 301, or buffer or relay data from the memory cell array 301.

Referring back to FIG. 5, in a solution of 4.5 bit/cell, increasing the read margin is one of the important means to improve reliability. Examples of the present disclosure provide a semiconductor device and a programming method thereof, which can increase a read margin to meet a reliability requirement of a product. The semiconductor device includes a memory cell array, word lines coupled with the memory cell array, and a peripheral circuit coupled with the word lines. The peripheral circuit is configured to:
perform a programming operation on a plurality of memory cells coupled with a selected word line, such that threshold voltages of the plurality of memory cells form a plurality of initial threshold voltage distributions corresponding to a plurality of program states; wherein memory cells forming the same initial threshold voltage distribution constitute a subset;
perform a reprogramming operation on the plurality of memory cells, wherein the reprogramming operation includes: verifying the memory cells in each subset respectively, to select a memory cell in each subset of which a threshold voltage is within a predetermined region in an initial threshold voltage distribution corresponding to the subset; and applying one or more corresponding preset program pulses to the selected memory cell in each subset.

The semiconductor device in the examples of the present disclosure may be a memory device, which may be the memory device shown in any example in FIG. 1 to FIG. 6. The memory device includes a memory cell array comprising a plurality of memory cells arranged in an array, and the memory cells may be NAND flash memory cells. For example, the memory cell array may be the memory cell array 301 in FIG. 3 and FIG. 6, and the memory cells may be the memory cells shown in any example in FIG. 3 through FIG. 6.

The present disclosure below takes a single memory cell having one of 24 states to store 4.5 bits of data as an example to illustrate the programming method provided in the present disclosure.

The storage of 4.5 bits of data by a single memory cell may be realized by the storage of 9 bits of data by two memory cells together. If each memory cell has one of 24 states, the two memory cells may combine 24*24=576 combinations, e.g., 576 states. With reference to QLC and PLC, it can be understood that 2⁹=512 states are needed to realize storage of 9 bits of data, and 576 combinations combined by two memory cells can cover 512 states, thus each memory cell having 24 states may achieve the storage of 9 bits of data by the two memory cells.

The semiconductor device may perform a programming operation at the page level. Referring to FIG. 3, a row of memory cells coupled to the same word line and different bit lines is referred to as page 320. The semiconductor device may perform program and reprogramming operations simultaneously on all memory cells included in a page.

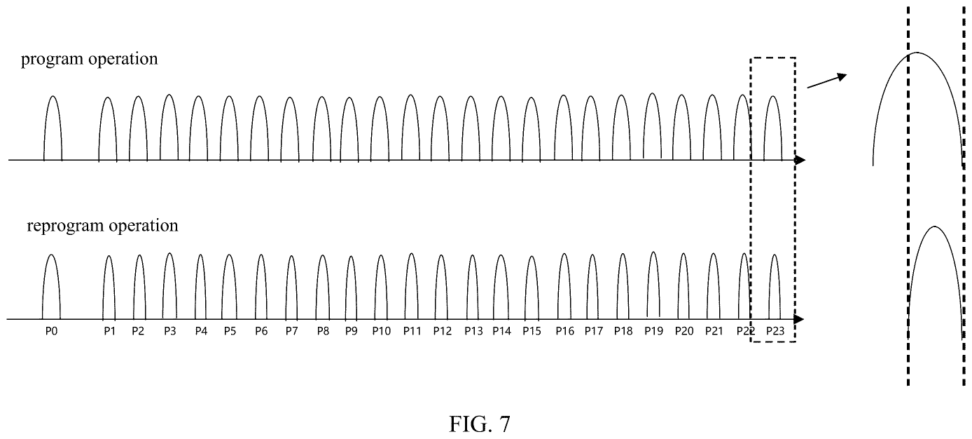

FIG. 7 is a schematic diagram of threshold voltage distributions of memory cells in a programming operation and a reprogramming operation provided by an example of the present disclosure. Referring to FIG. 7, after all memory cells included in a page undergo a programming operation, the threshold voltages of the memory cells may form a plurality of initial threshold voltage distributions corresponding to the plurality of program states P1 through P23 and a target threshold voltage distribution corresponding to the erase state P0.

In a programming operation, the memory cells of the erase state P0 may be inhibited from programming and keep the threshold voltages unchanged. The memory cells of the erase state P0 form a target threshold voltage distribution in a programming operation and would not be programmed in a reprogramming operation. The memory cells of the plurality of program states P1 through P23 are programmed differently according to data or information to be stored therein, forming a plurality of initial threshold voltage distributions corresponding to the plurality of program states P1 through P23. The program state P1 through the program state P23 correspond to 23 initial threshold voltage distributions. The two adjacent initial threshold voltage distributions among them may be isolated from each other in FIG. 7, that is, there is a smaller distance between two adjacent initial threshold voltage distributions.

A subset includes all memory cells forming the same initial threshold voltage distribution, which are also all memory cells forming the same target threshold voltage distribution. All memory cells in the subset are programmed to the same program state and store the same data or information. The data stored in all memory cells within the same subset is the same for SLC to QLC.

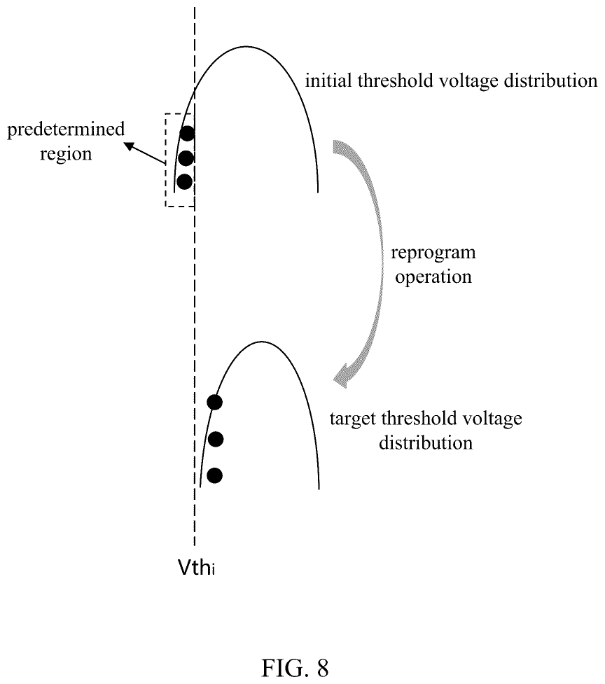

The reprogramming operation may be performed at a page level, that is, simultaneously performing a reprogramming operation on a page of memory cells coupled to the same word line, that is, simultaneously performing a reprogramming operation on all subsets coupled to the same word line. FIG. 8 shows a schematic diagram of performing a reprogramming operation on a subset. As shown in FIG. 8, in a reprogramming operation, all memory cells in the subset are verified, a memory cell of which a threshold voltage is within a predetermined region in the initial threshold voltage distribution is selected, one or more preset program pulses are applied to the selected memory cell, such that the threshold voltage of the selected memory cell is appropriately increased, and the non-selected memory cell is inhibited from being programmed in the reprogramming operation. Thus, the threshold voltage distribution can be narrowed by just increasing the threshold voltage of the selected memory cell, resulting in a more narrow and more concentrated target threshold voltage distribution than the initial threshold voltage distribution, thereby increasing the read margin.

In the initial threshold voltage distributions corresponding to different program states, the range of the predetermined region in the initial threshold voltage distribution may be the same or different. The range of the predetermined region may be adjusted according to the respective initial threshold voltage distribution of each program state. For example, if the initial threshold voltage distribution is wider, the predetermined region may be a larger region set at the tail to select more memory cells. If the initial threshold voltage distribution is narrower, the predetermined region may be a smaller region set at the tail to select fewer memory cells. It can be understood that the actual programming operation is affected by many factors, and it is difficult to perform according to a predetermined region designed in theory, thus in the actual program, the ranges of the predetermined regions of different program states in the initial threshold voltage distribution may be different.

With continued reference to FIG. 7, a reprogramming operation is performed on each of the 23 subsets corresponding to program state P1 through program state P23, such that 23 initial threshold voltage distributions change to 23 target threshold voltage distributions. The target threshold voltage distribution of each program state is narrower than the initial threshold voltage distribution, such that the read margin between adjacent target threshold voltage distributions is greater than the read margin between adjacent initial threshold voltage distributions, the error rate in the read operation can be reduced, and the reliability of the semiconductor device is improved.

In some examples, referring to the partial enlarged diagram in FIG. 7 and FIG. 8, by controlling the voltage magnitude of the preset program pulse, the target threshold voltage distribution may not be moved towards the direction in which the threshold voltage increases (e.g., the right side in the figure), that is, the head of the target threshold voltage distribution is substantially aligned with the head of the initial threshold voltage distribution, and just the threshold voltage of the memory cell at the tail of the initial threshold voltage distribution is increased, the initial threshold voltage distribution is narrowed, as such, a larger read margin can be obtained.

In some examples, the threshold voltages of some memory cells after the programming operation may be reduced due to the effect of IVS (Initial Voltage shift), such that the initial threshold voltage distributions at different time instances after the programming operation may be offset to the direction in which the threshold voltage decreases (e.g., the left side in FIG. 7). However, the initial threshold voltage distribution in the examples of the present disclosure refers to the initial threshold voltage distribution when the reprogramming operation is performed, that is, the initial threshold voltage distribution after being affected by the IVS. The reprogramming operation may increase the threshold voltage of the memory cell within the predetermined region (e.g., the tail of the initial threshold voltage distribution) to reduce the effect of the IVS on the threshold voltage distribution, thereby improving the accuracy of the read operation of the memory cell and improving the reliability of the memory cell.

In addition, in the example shown in FIG. 7, all memory cells of a page form 23 initial threshold voltage distributions corresponding to the 23 program states after undergoing a programming operation, and form 23 target threshold voltage distributions after undergoing a reprogramming operation. While in some other examples, all memory cells of a page may also form an initial threshold voltage distribution and a target threshold voltage distribution of some of the 23 program states, depending on the data or information stored in the page. It should also be noted that, the programming method provided by the examples of the present disclosure is not just applicable to a semiconductor device of 4.5 bit/cell, but also applicable to a semiconductor device of other multi level cell such as an MLC, a TLC, a QLC, and a PLC, which may obtain a narrower target threshold voltage distribution of program states, thereby obtaining a larger read margin and improving read reliability.

In some examples, the predetermined regions in different initial threshold voltage distributions are the regions in the initial threshold voltage distribution in which the threshold voltages are smaller than the corresponding preset threshold voltages. During verification of the memory cells of any subset, the peripheral circuit is configured to: provide a corresponding preset verification voltage related to the corresponding preset threshold voltage to the memory cells in the subset, and select a memory cell that is turned on at the preset verification voltage.

With continued reference to FIG. 8, the predetermined region may be a region in the initial threshold voltage distribution in which the threshold voltage is smaller than the preset threshold voltage Vthᵢ. In this way, on one hand, after all the memory cells with the threshold voltage less than the preset threshold voltage in the subset are selected and programmed, the threshold voltage distribution can be narrowed; on the other hand, the verification operations performed to select the memory cells with the threshold voltage less than the preset threshold voltage are relatively simple, and the time of reprogramming operation can be shortened, thereby achieving the relative balance between the programming operation time and the program accuracy.

For different program states, the respective preset threshold voltages Vthᵢ are different. It can be understood that the preset threshold voltage Vthᵢ is located in the initial threshold voltage distribution, and therefore, the preset threshold voltages Vthᵢ corresponding to respective program states are different due to their respective different initial threshold voltage distributions.

As described above, in the initial threshold voltage distribution of different program states, the proportion of the predetermined regions in the initial threshold voltage distribution may be the same or different. Accordingly, in this example, the positions of the preset threshold voltages Vthᵢ corresponding to respective program states in their respective initial threshold voltage distributions may be the same or different. Moreover, in the actual programming operation, the positions of the preset threshold voltages Vthᵢ in the initial threshold voltage distributions of different program states may be different.

In some examples, each initial threshold voltage distribution presents a normal distribution, and a range of the preset threshold voltages is less than or equal to μ−2σ, where μis a mean value of the initial threshold voltage distribution, and σ is a standard deviation of the initial threshold voltage distribution.

Referring to FIG. 7 and FIG. 8, the initial threshold voltage distribution of each of the erase state P0 and the program states P1 through P23 substantially presents a normal distribution. It can be understood that the actual initial threshold voltage distribution can just be approximately normal distribution due to many factors. The range of preset threshold voltages is less than or equal to μ−2σ, which means that the preset threshold voltage may be any value in the initial threshold voltage distribution and less than or equal to μ−2σ. For example, the preset threshold voltage may be μ−2σ, or μ−3σ, etc.

Taking the preset threshold voltage being μ−2σ as an example, the predetermined region is a range less than or equal to μ−2σ, that is, the tail of the initial threshold voltage distribution after μ−2σ.In normal distribution, the probability that the value falls in (μ−2σ, μ+2σ) is 0.9544, and the probability that the value falls outside of (μ−2σ, μ+2σ) is approximately 5%. Considering the deviation between the actual initial threshold voltage distribution and the normal distribution, it can also be understood that, in this example, just a small number of memory cells at the tail of the initial threshold voltage distribution are reprogrammed, increasing their threshold voltages, and thereby narrowing the threshold voltage distribution.

It should be noted that the preset threshold voltage provided by the examples of the present disclosure is merely an example. In other examples, the preset threshold voltage may also be set to be larger, for example, μ−σ and the like. It can be understood that, the larger the preset threshold voltage, the more the selected memory cells, such that the threshold voltage distribution of the selected memory cells is wider. In a reprogramming operation, fine program is required to prevent the memory cells with a larger threshold voltage from over programming, which causes the threshold voltage distribution moving to the right, but the fine program results in an extended reprogramming operation time. That is, the number of the selected memory cells is too large, which may not be conducive to narrowing the threshold voltage distribution by simple program. Then, in actual operation, an appropriate preset threshold voltage may be selected by comprehensively considering the time of reprogramming operation and the effect of narrowing the threshold voltage distribution.

In some examples, during verification of the memory cells of any of the subsets, the peripheral circuit may be configured to: apply, by the word line driver (e.g., row decoder/WL driver 508 in FIG. 6), a verify voltage (e.g., a preset verify voltage) to the selected word line to apply the verify voltage to the gates of the memory cells within the subset. At the verify voltage, the memory cells are turned on to different degrees according to different threshold voltages. The smaller the threshold voltage of the memory cell, the greater the degree of turn-on, and the larger the threshold voltage, the smaller the degree of turn-on.

In the peripheral circuit, a sensing node of a page buffer (e.g., page buffer 504 in FIG. 6) is coupled to the bit line and is pre-charged, and when the sensing node and the bit line are turned on, different currents are generated in the bit lines according to different degrees of turn-on of the memory cell, resulting in changes of different degrees of voltage of the sensing node. The page buffer may determine the degree of turn-on of the memory cell according to the comparison between the voltage of the sensing node after a time period of sensing and the reference voltage. If the voltage of the sensing node is less than the reference voltage, it indicates that the degree of turn-on of the memory cell is large, and the memory cell is considered to be turned on; and if the voltage of the sensing node is greater than the reference voltage, it indicates that the degree of turn-on of the memory cell is small, and the memory cell is considered to be not turned on. The selected memory cell which is turned on is a memory cell with a threshold voltage less than a preset threshold voltage.

The preset verification voltage and the sensing time used during verification are related to a preset threshold voltage. The memory cell with the threshold voltage less than the preset threshold voltage can be selected by adjusting the preset verification voltage and the sensing time. In some examples, the preset verification voltage may be equal to the preset threshold voltage.

In some examples, the reprogramming operation includes a plurality of program loops, each comprising a verify operation and a programming operation followed to the verify operation. During execution of each program loop, the peripheral circuit is configured to: verify the memory cells of a subset in the verify operation; and apply a corresponding preset program pulse to the selected memory cells in the subset in the programming operation.

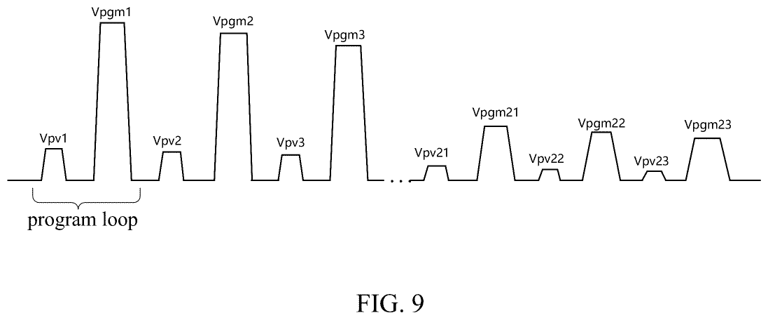

Just one of the subsets is verified and programmed in each program loop. For ease of description, a subset that is verified and programmed in the current program loop is referred to as a selected subset, while other subsets other than the selected subset are referred to as non-selected subsets. FIG. 9 illustrates a signal on a selected word line in a reprogramming operation. Referring to FIG. 9, the reprogramming operation includes a plurality of program loops, and in the verify operation of each program loop, the peripheral circuit may be configured to: apply, by the word line driver, a verify pulse to the selected word line, where the voltage of the verify pulse is the preset verify voltage Vpv corresponding to the selected subset in the program loop. In the verify operation, the word line driver applies a program pass voltage Vpass to the non-selected word line, and the page buffer can select the memory cell that is turned on at the preset verify voltage by the voltage change of the sensing node. Meanwhile, in the verify operation, the bit lines coupled to the memory cells in the non-selected subset may be applied with an inhibit program voltage (e.g., high voltage Vdd) to inhibit verification of the memory cells of the non-selected subset.

In the programming operation, the peripheral circuit may be configured to:
apply, by the word line driver, a preset program pulse to the selected word line, where a voltage of the preset program pulse is the program voltage Vpgm. The word line driver applies a program pass voltage Vpass to the non-selected word line. The page buffer applies a different bit line voltage to the bit line coupled to the memory cell, where the page buffer applies an inhibit program voltage (e.g., high voltage Vdd) to the bit line coupled with the non-selected subset, and also applies an inhibit program voltage to the bit line coupled with the non-selected memory cell in the selected subset (e.g., the memory cell that is not turned on at the preset verify voltage). The page buffer will also allow a program voltage (e.g., ground voltage Vss) to be applied to the bit lines coupled to the selected memory cells of the select subsets. The gate of the selected memory cell is applied with a program voltage Vpgm, the source is coupled to the bit line and is applied with a ground voltage Vss, the selected memory cell pulls electrons in the channel layer into the storage layer at the gate-source voltage, thereby increasing the threshold voltage.

It should be noted that since the bit lines to which the memory cells in the unselect subset and non-selected memory cells in the selected subset are coupled are applied with the inhibit program voltage (e.g., high voltage Vss), such that the gate-source voltages of these memory cells are smaller and the threshold voltages cannot be changed, therefore the program pulses applied on the selected word line are considered to be not applied to these memory cells.

In different program loops, memory cells in a predetermined region may be selected by a verify pulse. A preset program pulse is applied to the selected memory cells to increase the threshold voltage. Since the preset threshold voltages corresponding to different program states are different, the preset verify voltages Vpv of the verify pulses in the plurality of program loops are different. For example, the preset verify voltage corresponding to the subset with a higher initial threshold voltage distribution is larger, that is, the preset verify voltage Vpv corresponding to the subset is gradually decreased in the order of P23 through P1. The voltages of the preset program pulses used by the plurality of program loops may not be identical. For example, the voltage Vpgm of the preset program pulse corresponding to the subset with a higher initial threshold voltage distribution is larger, that is, the Vpgm of the preset program pulse corresponding to the subset is decreased in the order of P23 through P1.

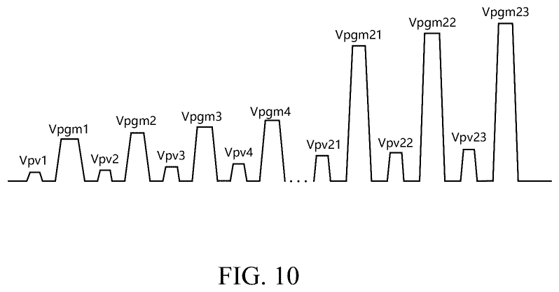

In some examples, as shown in FIG. 9, the preset program pulses may be applied in a descending order of the voltages of the preset program pulses, that is, Vpgm1>Vpgm2>Vpgm3 . . . >Vpgm23. The voltages of the verify pulses are also shown in a decreasing order, e.g., Vpv1>Vpv2>Vpv3 . . . >Vpv2l . In some other examples, as shown in FIG. 10, the preset program pulses may also be applied in an ascending order of the voltages of the preset program pulses, that is, Vpgm1<Vpgm2<Vpgm3 . . . <Vpgm23. The voltages of the verify pulses are also shown in an ascending order, that is, Vpv1<Vpv2<Vpv3 . . . <Vpv23. In addition, the voltage and the pulse width (that is, the program time) of the preset program pulse are not limited in the present disclosure, and the preset program pulse with better (comprising optimal) effect on narrowing the threshold voltage distribution can be determined through multiple experimental voltages.

In this example, by just applying one verify pulse and one program pulse to each subset, the threshold voltage distribution can be narrowed with a shorter reprogramming operation time, improving the reliability of the semiconductor device.

In some examples, the reprogramming operation includes: a verify stage and a program stage followed to the verify stage; the peripheral circuit is configured to: verify the memory cells in each subset in the verify stage respectively; and apply one or more corresponding preset program pulses to the selected memory cells in each subset in the program stage.

In this example, by first completing the verification of the plurality of subsets together, and then performing the reprogramming operation on the scheme in which the selected memory cells in the plurality of subsets are programmed together, the word line preparation time and the bit line preparation time can be saved, thereby shortening the time of the reprogramming operation.

For example, in the verify stage, the peripheral circuit may be configured to: apply in sequence, by the word line driver, a plurality of verify pulses with different preset verify voltages to the selected word line. The number of the verify pulses is equal to the number of the plurality of subsets, where one verifies pulse is configured to have a preset verify voltage corresponding to one of the subsets to verify the memory cells in the subset.

The order in which the plurality of verify pulses are applied is not limited in the present disclosure. In some examples, the plurality of verify pulses may be applied to the selected word line in an ascending order of the preset verify voltages. In some other examples, the plurality of verify pulses may be applied to the selected word line in a descending order of the preset verify voltage.

In the verify stage, the peripheral circuit is further configured to: apply, by the word line driver, a program pass voltage to the non-selected word lines, and the page buffer performs different operations in different time periods. Taking the page buffer coupled with any subset as an example, when the subset is the selected subset, that is, the preset verify voltage on the selected word line is configured to verify the subset, the page buffer senses the voltage change on the bit line, thereby selecting the memory cell that is turned on at the preset verify voltage in the selected subset as the selected memory cell. When the subset is a non-selected subset, the page buffer may apply an inhibit program voltage to the bit line.

In some examples, in the program stage, the peripheral circuit is configured to: apply a preset program pulse to the selected word line, wherein the falling edge of the preset program pulse includes multiple steps; apply an allowed program voltage to the bit line coupled to each subset in sequence in a descending order of the initial threshold voltage distributions corresponding to the subset; wherein when the preset program pulse reaches the maximum voltage, apply the allowed program voltage to the bit line coupled to the selected memory cell in the subset corresponding to the highest initial threshold voltage distribution, and each time a voltage of the preset program pulse drops to the step, apply the allowed program voltage correspondingly to the bit line coupled to the selected memory cell in the subset.

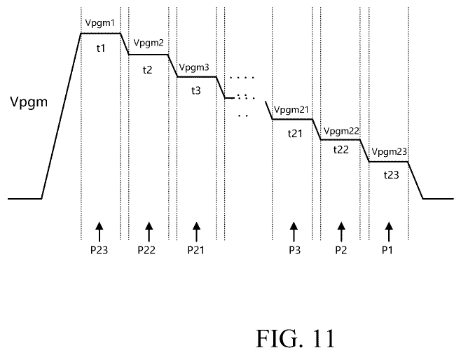

FIG. 11 is a schematic diagram of a preset program pulse on a selected word line in a program stage provided by an example of the present disclosure. Referring to FIG. 11, the voltage of the preset program pulse is firstly increased to the maximum voltage Vpgm1, and then the voltage is decreased step by step, such that the falling edge of the preset program pulse has multiple steps. The total number of the step where the maximum voltage is located and all steps of the falling edge is equal to the number of the plurality of initial threshold voltage distributions corresponding to the plurality of program states.

In FIG. 11, taking the memory cells coupled to a selected word line being divided into 24 subsets as an example for illustration, wherein the program states P1 through P23 correspond to 23 initial threshold voltage distributions, then the preset program pulse has 23 steps comprising a maximum voltage. The program voltages at each of the 23 steps in a descending order of voltages are Vpgm1, Vpgm2, Vpagm3, . . . , Vpgm21, Vpgm22, and Vpgm23. The program time at each level of step, that is, the duration of the horizontal section of the step, is: Vpgm1 which lasts t1 time, Vpgm2 which lasts t2 time, Vpgm3 which lasts t3 time, . . . , Vpgm21 which lasts t21 time, Vpgm22 which lasts t22 time, and Vpgm23 which lasts t23 time, respectively.

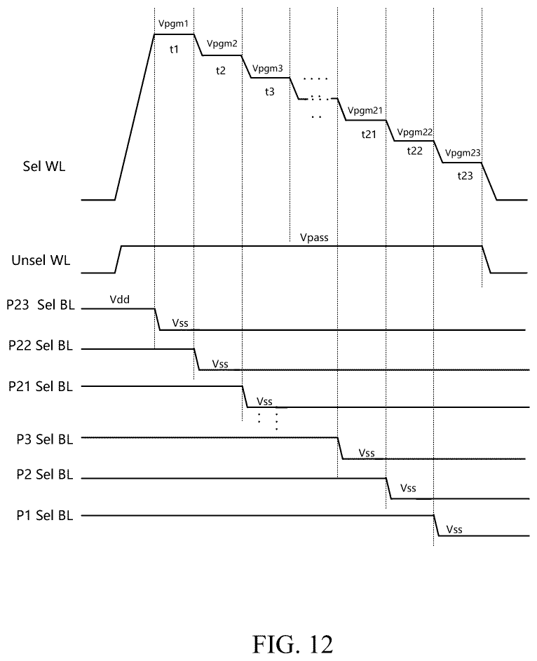

FIG. 12 is a third schematic diagram of a reprogramming operation provided by an example of the present disclosure. Referring to FIGS. 11 and 12, the plurality of page buffers provide an allowed program voltage to the bit line coupled to the selected memory cell in each subset in a descending order of the initial threshold voltage distributions corresponding to the subset. In this example, the subset is ordered in a descending order of the initial threshold voltage distributions corresponding to subset as a subset of P23, a subset of P22, a subset of P21, . . . , a subset of P3, a subset of P2, and a subset of P1, respectively.

Referring to FIG. 12, when the preset program pulse reaches the maximum voltage Vpgm1, the bit line (P23 Sel BL) coupled to the selected memory cell in the subset of P23 is provided with the allowed program voltage (e.g., the ground voltage Vss), and in this case, the threshold voltage of the selected memory cell in the subset of P23 increases at the program voltage Vpgm1.

When the voltage of the preset program pulse drops to Vpgm2, the bit line (P22 Sel BL) coupled to the selected memory cell in the subset of P22 is provided with the allowed program voltage Vss, and in this case, the threshold voltage of the selected memory cell in the subset of P22 increases at the program voltage Vpgm2; meanwhile, since the allowed program voltage is still on the P23 Sel BL, such that the selected memory cell in the subset of P23 is also applied with the program voltage Vpgm2. That is, when the voltage of the preset program pulse drops to Vpgm2, the selected memory cell in the subset of P23 has undergone the program voltage Vpgm2 and Vpgm1, and the selected memory cell in the subset of P22 has undergone the program voltage Vpgm2.

When the voltage of the preset program pulse continues to drop to Vpgm3, the bit line (P22 Sel BL) coupled to the selected memory cell in the subset of P21 is provided with the allowed program voltage Vss, and in this case, the selected memory cell in the subset of P21 is applied with the program voltage Vpgm3, while the selected memory cell in the subset of P23 and the selected memory cell in the subset of P22 are also applied with the program voltage Vpgm3. That is, when the voltage of the preset program pulse drops to Vpgm3, the selected memory cell in the subset of P23 has undergone three program voltages, the selected memory cell in the subset of P22 has undergone two program voltages, and the selected memory cell in the subset of P21 has undergone one program voltage.

According to the above operation, each time a voltage of the preset program pulse drops to the step, the allowed program voltage Vss is correspondingly applied to the bit line coupled to the selected memory cell in one of the subsets. Moreover, the bit lines that have been previously applied with the allowed program voltage continue to be applied with the allowed program voltage, such that when the selected memory cell in a certain subset is applied with the program voltage, other subsets with the initial threshold voltage distribution higher than that of the subset are also applied with the associated program voltage. Eventually, the higher the initial threshold voltage distribution of the subset, the longer the time the subset is applied with the program voltage, and the lower the initial threshold voltage distribution of the subset, the shorter the time the subset is applied with the program voltage. As shown in FIG. 12, the selected memory cell in the subset of P23 is applied in sequence with the program voltages Vpgm1 through Vpgm23 in the time period of t1 through t23, the selected memory cell in the subset of P22 is applied in sequence with the program voltages Vpgm2 through Vpgm23 in the time period t2 through t23, and so on, the selected memory cell in the subset of P2 is applied in sequence with the program voltages Vpgm 22 and Vpgm23 in the time period t22 through t23, and the selected memory cell in the subset of P1 is applied with the program voltage Vpgm23 just in the time period of t23.

In comparison to applying the program pulse one by one in FIG. 9, this way of changing the program voltage in the preset program pulse can save the reprogramming operation time. It can be understood that, each time a program pulse is applied, the word line voltage setting and the bit line voltage setting require a preparation time, and in this example, just one preset program pulse shown in FIG. 12 is applied, and the preparation time can be saved, thereby saving the reprogramming operation time.

In addition, for a memory string in which a non-selected memory cell is located (hereinafter referred to as a non-selected string), wherein the non-selected memory cell comprises a memory cell in a non-selected subset and a unselected memory cell in the subset, the gate of the lower select transistor of the non-selected string is applied with a ground voltage to turn off the lower select transistor; the gate of the upper select transistor is applied with a high voltage, the source of the upper select transistor is coupled to the bit line and is applied with Vdd because the bit line is applied with the inhibit program voltage Vdd, the gate-source voltage of the upper select transistor is insufficient to turn on the upper select transistor and the upper select transistor is turned off, which causes the channel of the non-selected string to be in the floating state. When the non-selected word line to which the select string (e.g., the memory string in which the selected memory cell is located) and the non-selected string commonly coupled together is applied with the program pass voltage Vpass, as the voltage rises from 0V to the program pass voltage Vpass, in the channel of the non-selected string, one potential is coupled due to the Vpass voltage applied to the other side of the gate oxide capacitor, thereby inhibiting the programming of the memory cell coupled to the non-selected string. When a certain non-selected memory string becomes a selected memory string, the channel potential may be released. For example, in FIG. 12, when the selected memory cell in the subset of P22 is to be programmed, the voltage of the bit line is changed from the inhibit program voltage to the allowed program voltage, such that the upper select transistor is turned on, and the potential in the channel is released.

If it is desired to change a certain selected string to a non-selected string, not only the voltage of the bit line needs to be set to the program-inhibit voltage, but also the voltage of the non-selected word line needs to be risen from 0V to the program pass voltage Vpass again to recouple the potential in the channel. Therefore, in this example, the program voltage in the preset program pulse is reduced from high to low, such that the voltage setting time of the non-selected word line can be saved, thereby shortening the reprogramming operation time. It can be understood that if the program voltage of the preset program pulse is set from low to high, the period of time cannot be saved.

In addition, for a subset with a higher initial threshold voltage distribution, such as a subset of P23, the program time is not expected to be particularly long, and the program voltage is not expected to be particularly high, and if the time is longer or the program voltage is higher, the threshold voltage of the memory cell may be excessively increased, reaching a region with the head greater than μ+3σ, and the threshold voltage distribution cannot be narrowed. However, in this example, each time a program voltage is not large, the memory cell with a larger threshold voltage in the selected memory cells may be firstly programmed into the (μ−3σ, μ+3σ) region of the initial threshold voltage distribution by Vpgm1, while other memory cells with a lower threshold voltage may be gradually programmed into the (μ−3σ, μ+3σ) region by a plurality of subsequent program voltages. In this way, since the memory cells with different threshold voltages are programmed at different program voltages, the threshold voltage is not easy to excessively increase, which facilitates narrowing the threshold voltage distribution.

For example, the program voltage at each step is determined based on the corresponding subset, while other subsets have incidental effect. Moreover, for memory cells in the subset which pass programming, an inhibit program voltage (e.g., high voltage Vdd) is always applied on the bit line in the program stage.

In some examples, before a reprogramming operation is performed on the plurality of memory cells, two programming operations comprising a first programming operation and a second programming operation are performed on the plurality of memory cells; the peripheral circuit is configured to:
perform the first programming operation on the plurality of memory cells, such that the threshold voltages of the plurality of memory cells form a plurality of intermediate distributions;
perform the second programming operation on the plurality of memory cells, such that the plurality of intermediate distributions are changed to a plurality of initial threshold voltage distributions corresponding to a plurality of program states.

Before the reprogramming operation, one or more programming operations may be performed on the memory cells coupled to the selected word line to form the plurality of initial threshold voltage distributions. In this example, before the reprogramming operation, the plurality of initial threshold voltage distributions are formed by two programming operations.

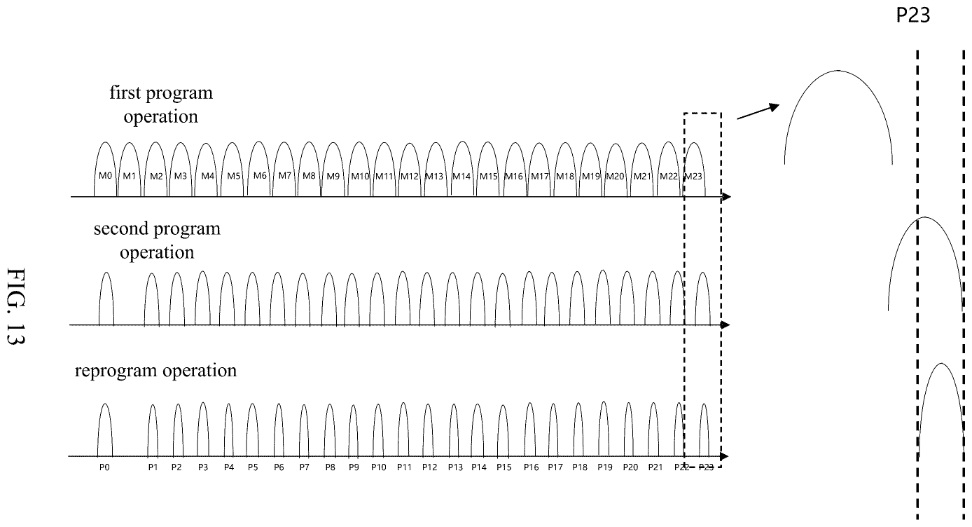

FIG. 13 is a first schematic diagram of a programming scheme provided by an example of the present disclosure. Referring to FIG. 13, the threshold voltages of a page of memory cells may form a plurality of intermediate distributions by a first programming operation. The number of the intermediate distributions may be equal to the number of the initial threshold voltage distributions, for example, in this example, the plurality of memory cells form 24 intermediate distributions, the number of which are equal to the number of the initial threshold voltage distributions.

The 24 intermediate distributions are numbered in sequence from low to high, for example, the lowest intermediate distribution is M0, and the other intermediate distributions are M1, M2, . . . , M23 in sequence. The memory cells in any one of the intermediate distributions may be programmed into the same initial threshold voltage distribution as its serial number after the second programming operation, or may be programmed into an initial threshold voltage distribution with a greater serial number than it. For example, the memory cells in the intermediate distribution M0 may be programmed into the initial threshold voltage distribution corresponding to the program state P1, or may not be programmed and in the target threshold voltage distribution corresponding to the erase state P0. In other words, although the number of intermediate distributions is equal to the sum of the number of states of the erased state and the programmed state, it is not meant that the memory cells in the intermediate distribution belong to one of the subsets, instead the memory cells in the intermediate distribution may belong to one of the subsets, or may belong to two or more subsets.

In the first programming operation, each of the memory cells that are to be programmed into different intermediate distributions M1 through M23 are allowed to be programmed and have a threshold voltage greater than the threshold voltage greater when being in the initial state. The memory cells in the intermediate distribution M0 after the first programming operation may be inhibited from programming in the first programming operation and have the same threshold voltage as the initial state. The initial state is a state in which a programming operation has not been performed after the memory cell is erased.

For example, the first programming operation may be performed with incremental step pulse program (ISPP). Alternatively, in other examples, the first programming operation may be performed in other program manners. This is not limited in the present disclosure.

With continued reference to FIG. 13, the plurality of intermediate distributions may be converted into initial threshold voltage distributions corresponding to the plurality of program states by the second programming operation. The initial threshold voltage distribution may be considered to have been close to the target threshold voltage distribution, but there are still a small number of memory cells whose threshold voltages are less than the target threshold voltage distribution, for example, the memory cells in the −3σ range of the tail of the initial threshold voltage distribution are not within the target threshold voltage distribution.

In the second programming operation, for any one of the intermediate distributions M1 through M23, each memory cell in the intermediate distribution may be programmed. For the intermediate distribution M0, if each memory cell in the intermediate distribution M0 is finally in the erase state P0, programming is inhibited; if some of the memory cells in the intermediate distribution M0 are finally programmed to the program state, the some of the memory cells are programmed and the memory cells finally in the erase state P0 are inhibited from programming. As shown in FIG. 13, in this example, some of the memory cells in the intermediate distribution M0 are programmed to a program state, such that the target threshold voltage distribution corresponding to the erase state P0 is more narrow relative to the intermediate distribution M0.

A difference between the reprogramming operation and the second programming operation is that the reprogramming operation first verifies the memory cells in each subset, and then applies program pulses to the selected memory cells to program, that is, the program objects are selected memory cells in the subset. The second programming operation first applies program pulses to program and then verifies, and the program objects are all memory cells of the subset. As shown in FIG. 13, the reprogramming operation may move the tail of the initial threshold voltage distribution to the right, thereby narrowing the initial threshold voltage distribution to obtain the target threshold voltage distribution. For example, the second programming operation may be performed with the ISPP.

The number of the intermediate distributions is not limited in the present disclosure. In some other examples, the number of intermediate distributions may be less than the number of initial threshold voltage distributions. For example, the number of intermediate distributions may be 3, that is, S0, S1, and S2, respectively. In the first programming operation, the memory cells to be programmed to the P0 through P7 states are first programmed into the intermediate distribution S0, the memory cells to be programmed to the P8 through P15 states are first programmed into the intermediate distribution S1, and the memory cells to be programmed to the P16 through P24 states are first programmed into the intermediate distribution S2. In the second programming operation, the memory cells in the respective intermediate distributions are then programmed into the corresponding initial threshold voltage distributions.

In some examples, the number of word lines is multiple, and the peripheral circuit is further configured to: after the first programming operation is performed on the memory cell coupled to the selected word line and before the second programming operation and the reprogramming operation are successively performed, perform in sequence the second programming operation and the reprogramming operation on memory cells coupled to the previous word line successively, and perform the first programming operation on memory cells coupled to the next word line.

The reprogramming operation and the last one of the multiple programming operations are performed successively. In this example, two programming operations are performed before the reprogramming operation, then the reprogramming operation is performed successively with the second programming operation. In some other examples, if three programming operations are performed before the reprogramming operation, the reprogramming operation is performed successively with the third programming operation.

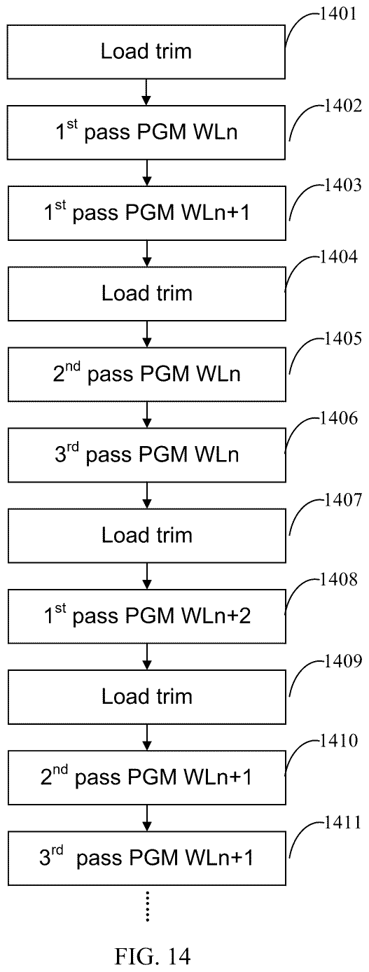

FIG. 14 is a first flowchart of a programming scheme provided by an example of the present disclosure. As shown in FIG. 14, the trim parameters are loaded (load trim 1401), where the trim parameters include a set of operational parameters for the memory cell: e.g., voltage, current, temperature compensation, power, etc. The firmware or peripheral circuit may use the trim parameters to adjust some of the parameters on the corresponding control circuit (e.g., voltage generator). The trim parameters may be stored in relevant registers in the peripheral circuit.

After the trim parameters of the memory cells coupled to word lines WLn and WLn+1 are loaded, a first programming operation (1^{st} pass PGM WLn 1402) is performed on memory cells coupled to word line WLn, and a first programming operation (1^{st} pass PGM WLn+1 1403) is performed on memory cells coupled to a next word line WLn+1 adjacent to the word line WLn. Then, the trim parameters of the memory cells coupled to the word line WLn are loaded (load trim 1404), and a second programming operation (2^{nd} pass PGM WLn 1405) and a reprogramming operation (3^{nd} pass PGM WLn 1406) are successively performed on the memory cells coupled to the word line WLn. It should be noted that, since the word line WLn is the first word line which is programmed, the second programming operation and the reprogramming operation are not successively performed on the memory cell coupled to the pervious word line between the first programming operation and the second programming operation performed on the memory cell coupled to the word line WLn.

With continued reference to FIG. 14, the trim parameters of the memory cells coupled to the word line WLn+2 are loaded (load trim 1407), and a first programming operation (1^{st} pass PGM WLn+2 1408) is performed on the memory cells coupled to the word line WLn+2. The trim parameters of the memory cells coupled to the word line WLn+1 are loaded again (load trim 1409), and a second programming operation (2^{nd} pass PGM WLn+1 1410) and a reprogramming operation (3^{nd} pass PGM WLn+1 1411) are successively performed on the memory cells coupled to the word line WLn+1.

If the word line WLn+1 is used as the selected word line, it can be clearly seen that after the first programming operation is performed on the memory cell coupled to the selected word line WLn+1 and before the second programming operation and the reprogramming operation are performed successively, the second programming operation and the reprogramming operation are successively performed in sequence on the memory cell coupled to the previous word line WLn, and the first programming operation is performed on the memory cell coupled to the next word line WLn+2. Similarly, the programming operations on the remaining other word lines are completed. It should be further noted that after the first programming operation on the last programmed word line is completed, the second programming operation and the reprogramming operation are successively performed in sequence on the memory cell coupled to the pervious word line, and the second programming operation and the reprogramming operation on the last programmed word line are completed successively, and no programming is performed on the next word line.

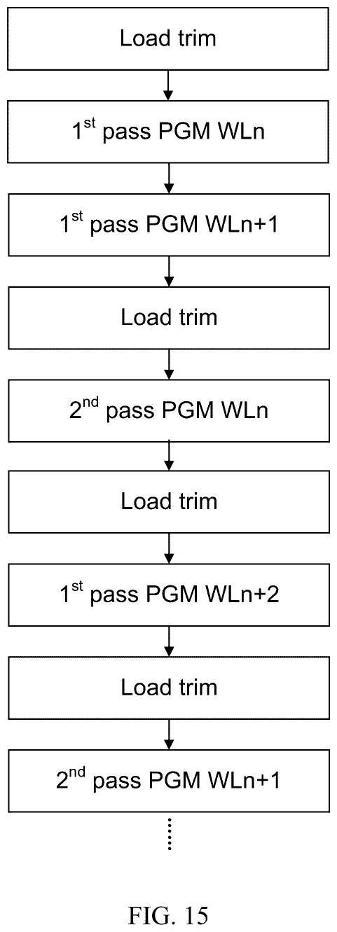

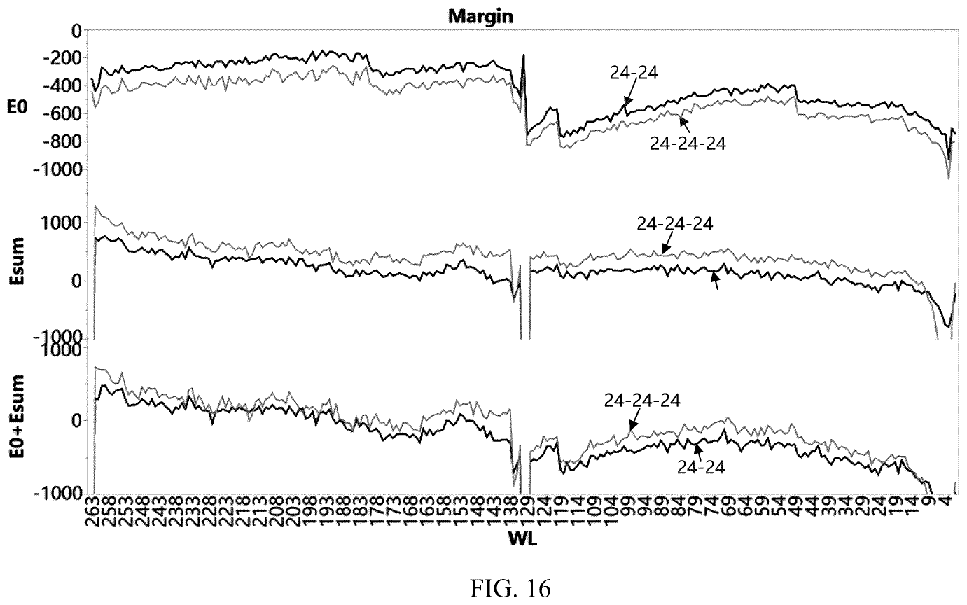

FIG. 16 is a schematic diagram of E0, Esum, and E0+Esum of two programming schemes provided by an example of the present disclosure. The 24-24-24 programming scheme is a programming scheme comprising a first programming operation, a second programming operation, and a reprogramming operation provided by FIGS. 13 and 14 of the present disclosure. The 24-24 programming scheme is the programming scheme shown in FIG. 15 of the present disclosure. The programming scheme in FIG. 15 differs from the programming scheme in FIG. 14 in that no reprogramming operation (3^{rd} pass PGM) provided by an example of the present disclosure is performed, while the first programming operation (1^{st} pass PGM) and the second programming operation (2^{nd} pass PGM) are the same as the first programming operation and the second programming operation in the scheme of FIG. 14.

The voltage interval between the target threshold voltage distribution corresponding to the erase state P0 and the target threshold voltage distribution corresponding to the program state P1 that can be configured to read the memory cells in the erase state P0 is referred to as the read margin E0, and the voltage interval between the target threshold voltage distribution corresponding to the erase state P0 and the target threshold voltage distribution corresponding to the program state P1 that can be configured to read the memory cells in the program state P1 is referred to as the read margin E1. That is, there are two read margins between every two adjacent target threshold voltage distributions, then in this example, each memory cell can be programmed to 24 states, Esum=E0+E1+E2+ . . . +E47.

The larger the read margin, and the larger the Esum, then the lower the probability of occurrence of read errors in the memory. In this example, as shown in FIG. 16, with the 24-24-24 programming scheme provided by the example of the present disclosure, Esum may be increased by about 200 mV, which may greatly reduce the probability of occurrence of read errors. With a 24-24-24 programming scheme, E0 is reduced by about 110 mV, and since E0 is a negative value, a smaller E0 indicates a larger distance between the target threshold voltage distributions of the erase state P0 and the program state P1, that is, it indicates that the target threshold voltage distribution of the program state P1 is narrower than in the 24-24 solution. The larger E0+Esum indicates the larger distance between the target threshold voltage distributions of every two adjacent program states in the plurality of program states P0 through P23. For example, the value of E0+Esum corresponding to a certain word line in the 24-24 solution is −297, and the E0+Esum corresponding to the word line in the 24-24-24 solution provided in this example is −194, which is greater, indicating that the larger the distance between the target threshold voltage distributions of two adjacent program states, the lower the probability of occurrence of read errors, and the accuracy of read can be improved.

In summary, with the method of the programming operation and the reprogramming operation in the examples of the present disclosure, each subset is verified in the reprogramming operation, a memory cell in a predetermined region of the tail is selected and programmed with a single pulse to appropriately increase the threshold voltage of the selected memory cell, thereby narrowing the threshold voltage distribution to obtain a better read margin.

An example of the present disclosure further provides a memory system, comprising one or more semiconductor devices provided by any one of the above examples of the present disclosure and a memory controller coupled to the semiconductor device and configured to control the semiconductor device.

For example, the memory system may be the memory of any one of FIG. 1 through FIG. 2b.

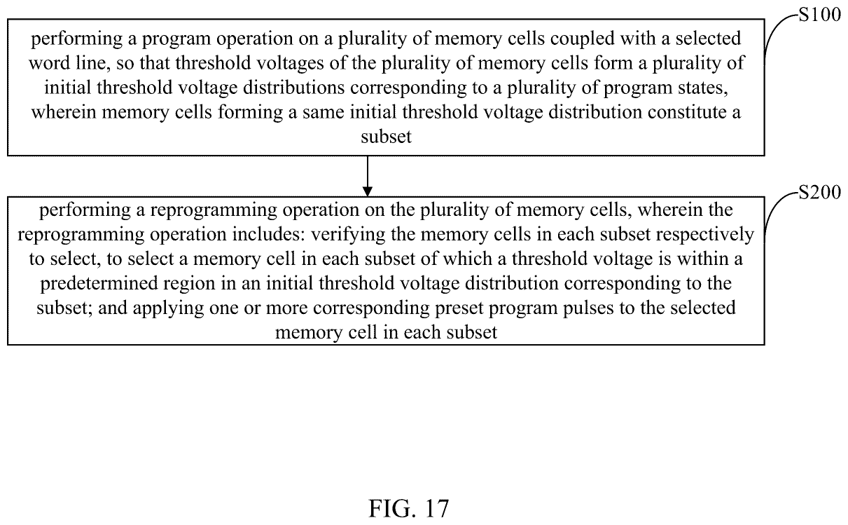

An example of the present disclosure further provides a programming method of a semiconductor device, and FIG. 17 is a schematic flowchart of a programming method provided by an example of the present disclosure. As shown in FIG. 17, the programming method includes:
S100: performing a programming operation on a plurality of memory cells coupled with a selected word line, such that threshold voltages of the plurality of memory cells form a plurality of initial threshold voltage distributions corresponding to a plurality of program states, wherein memory cells forming the same initial threshold voltage distribution constitute a subset;
S200: performing a reprogramming operation on the plurality of memory cells, wherein the reprogramming operation includes: verifying the memory cells in each subset respectively to select, to select a memory cell in each subset of which a threshold voltage is within a predetermined region in an initial threshold voltage distribution corresponding to the subset; and applying one or more corresponding preset program pulses to the selected memory cell in each subset.

In some examples, the predetermined regions in different initial threshold voltage distributions are the regions in the initial threshold voltage distributions in which the threshold voltages are smaller than the corresponding preset threshold voltages. In operation S200, verifying the memory cells in each subset respectively includes: for the memory cells in each subset, making the following operations:
providing a corresponding preset verify voltage related to a corresponding preset threshold voltage to the memory cells in the subset, and selecting a memory cell that is not turned on at the preset verify voltage, wherein different subsets correspond to different preset verify voltages.

In some examples, the reprogramming operation includes a plurality of program loops, each of the program loops comprises a verify operation and a programming operation followed to the verify operation. Operation S200 may be implemented by: performing the plurality of program loops in sequence, wherein during the execution of each program loop, the memory cells of a subset are verified in the verify operation, and a corresponding preset program pulse is applied to the selected memory cell in the subset in the programming operation.

In some examples, the reprogramming operation includes a verify stage and a program stage followed to the verify stage. Operation S200 may be implemented by: verifying the memory cells in each subset respectively in the verify stage; and applying a corresponding preset program pulse to the selected memory cell in each subset in the program stage.

In some examples, applying a corresponding preset program pulse to the selected memory cell in each subset in the program stage includes:
applying a preset program pulse to the selected word line, wherein the falling edge of the preset program pulse includes multiple steps;
providing an allowed program voltage to the bit line coupled to each subset in sequence in a descending order of the initial threshold voltage distributions corresponding to the subsets, wherein when the preset program pulse reaches the maximum voltage, a bit line coupled to a selected memory cell in a subset corresponding to the highest threshold voltage distribution is provided with the allowed program voltage, and each time a voltage of the preset program pulse drops to the step, the allowed program voltage is correspondingly applied to the bit line coupled to the selected memory cell in a subset.

According to the programming method of executing the reprogramming operation after the programming operation provided by the example of the present disclosure, each subset is verified in the reprogramming operation, the memory cells in the predetermined region of the tail of the initial threshold voltage distribution corresponding to the subset are selected and programmed with a single pulse program to appropriately increase the threshold voltage of the selected memory cell, thereby narrowing the threshold voltage distribution and obtaining better read margin.

The features disclosed in the several apparatus examples provided by the present disclosure may be arbitrarily combined without conflict to obtain a new apparatus example.

The method disclosed in the several method examples provided by the present disclosure may be arbitrarily combined without conflict to obtain a new method example.

Examples of the present disclosure provide a semiconductor device, a programming method thereof, and a memory system.

According to a first aspect, an example of the present disclosure provides a semiconductor device, comprising: a memory cell array, word lines coupled with the memory cell array, and a peripheral circuit coupled with the word lines, wherein the peripheral circuit is configured to:
perform a programming operation on a plurality of memory cells coupled with a selected word line, such that threshold voltages of the plurality of memory cells form a plurality of initial threshold voltage distributions corresponding to a plurality of program states, wherein memory cells forming the same initial threshold voltage distribution constitute a subset; and
perform a reprogramming operation on the plurality of memory cells, wherein the reprogramming operation includes: verifying the memory cells in each subset respectively, to select a memory cell in each subset of which a threshold voltage is within a predetermined region in an initial threshold voltage distribution corresponding to the subset; and applying one or more preset program pulses to the selected memory cell in each subset.

According to a second aspect, an example of the present disclosure provides a memory system, comprising: one or more semiconductor devices according to any one of the first aspect of the present disclosure; and
a memory controller coupled to the semiconductor device and configured to control the semiconductor device.

According to a third aspect, an example of the present disclosure provides a programming method of a semiconductor device, comprising:
performing a programming operation on a plurality of memory cells coupled with a selected word line, such that threshold voltages of the plurality of memory cells form a plurality of initial threshold voltage distributions corresponding to a plurality of program states, wherein memory cells forming the same initial threshold voltage distribution constitute a subset; and
performing a reprogramming operation on the plurality of memory cells, wherein the reprogramming operation includes: verifying the memory cells in each subset respectively, to select a memory cell in each subset of which a threshold voltage is within a predetermined region in an initial threshold voltage distribution corresponding to the subset; and applying one or more corresponding preset program pulses to the selected memory cell in each subset.

In the programming scheme provided by the examples of the present disclosure, the threshold voltages of the memory cells in each subset may form a corresponding initial threshold voltage distribution by a programming operation. In a reprogramming operation, all memory cells of the subset are verified, a memory cell of which a threshold voltage is within a predetermined region in the initial threshold voltage distribution is selected, and one or more preset program pulses are applied to the selected memory cell, such that the threshold voltage of the selected memory cell is appropriately increased, and the non-selected memory cell is inhibited from being programmed in the reprogramming operation. In this way, the threshold voltage distribution can be narrowed by just increasing the selected memory cell, resulting in a more narrow and more concentrated target threshold voltage distribution than the initial threshold voltage distribution, thereby increasing a read margin, reducing a probability that a read error occurs in the semiconductor device, and ensuring performance of the semiconductor device while performing logical scaling.

The above descriptions are just specific aspects of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A semiconductor device, comprising:
a memory cell array;
word lines coupled with the memory cell array; and
a peripheral circuit coupled with the word lines, wherein the peripheral circuit is configured to:
perform a programming operation on a plurality of memory cells coupled with a selected word line, such that threshold voltages of the plurality of memory cells form a plurality of initial threshold voltage distributions corresponding to a plurality of program states, wherein memory cells forming the same initial threshold voltage distribution constitute a subset; and
perform a reprogramming operation on the plurality of memory cells, wherein the reprogramming operation includes:
verifying the memory cells in each subset respectively, to select a memory cell in each subset of which a threshold voltage is within a predetermined region in an initial threshold voltage distribution corresponding to the subset; and
applying one or more preset program pulses to selected memory cells in each subset.

2. The semiconductor device of claim 1, wherein predetermined regions in different initial threshold voltage distributions are the regions in the initial threshold voltage distributions in which the threshold voltages are smaller than the corresponding preset threshold voltages;
during the verification of the memory cells in each subset, the peripheral circuit is configured to:
apply a corresponding preset verify voltage related to a corresponding preset threshold voltage to the memory cells in the subset, and
select the memory cell that is turned on at the preset verify voltage.

3. The semiconductor device of claim 2, wherein each of the initial threshold voltage distributions presents a normal distribution; and
ranges of the preset threshold voltages are less than or equal to μ−2σ, wherein μis a mean value of the initial threshold voltage distribution, and σ is a standard deviation of the initial threshold voltage distribution.

4. The semiconductor device of claim 1, wherein the reprogramming operation includes a plurality of program loops, each of the program loops comprises a verify operation and a programming operation followed to the verify operation;
during each of the program loops, the peripheral circuit is configured to:
verify the memory cells of the subset in the verify operation; and
apply a corresponding preset program pulse to the selected memory cell in the subset in the programming operation.

5. The semiconductor device of claim 1, wherein the reprogramming operation includes: a verify stage and a program stage followed to the verify stage; and the peripheral circuit is configured to:
verify the memory cells in each subset respectively in the verify stage; and
apply a corresponding preset program pulse to the selected memory cell in each subset in the program stage.

6. The semiconductor device of claim 5, wherein in the program stage, the peripheral circuit is configured to:
apply a preset program pulse to the selected word line, wherein a falling edge of the preset program pulse includes multiple steps; and
provide an allowed program voltage to a bit line coupled to each subset in sequence in a descending order of the initial threshold voltage distributions corresponding to the subsets, wherein when the preset program pulse reaches a maximum voltage, a bit line coupled to a selected memory cell in a subset corresponding to a highest initial threshold voltage distribution is applied with the allowed program voltage, and each time a voltage of the preset program pulse drops to a step, the allowed program voltage is correspondingly applied to the bit line coupled to the selected memory cell in one of the subsets.

7. The semiconductor device of claim 6, wherein the threshold voltages of the plurality of memory cells form 23 initial threshold voltage distributions; and
in the program stage, the preset program pulse of the selected word line provided by the peripheral circuit has 23 steps comprising the maximum voltage.

8. The semiconductor device of claim 1, wherein two programming operations are performed on the plurality of memory cells before a reprogramming operation is performed on the plurality of memory cells, wherein the two programming operations comprises a first programming operation and a second programming operation;
the peripheral circuit is configured to:
perform the first programming operation on the plurality of memory cells, such that the threshold voltages of the plurality of memory cells form a plurality of intermediate distributions; and
perform the second programming operation on the plurality of memory cells, such that the plurality of intermediate distributions are changed to the plurality of initial threshold voltage distributions corresponding to the plurality of program states.

9. The semiconductor device of claim 8, wherein a number of word lines is multiple; and the peripheral circuit is further configured to:
after the first programming operation is performed on the memory cell coupled to the selected word line and before the second programming operation and the reprogramming operation are successively performed, perform in sequence the second programming operation and the reprogramming operation on memory cells coupled to a previous word line successively, and perform the first programming operation on memory cells coupled to a next word line.

10. A memory system, comprising:
a semiconductor device, comprising:
a memory cell array;
word lines coupled with the memory cell array; and
a peripheral circuit coupled with the word lines, wherein the peripheral circuit is configured to:
perform a programming operation on a plurality of memory cells coupled with a selected word line, such that threshold voltages of the plurality of memory cells form a plurality of initial threshold voltage distributions corresponding to a plurality of program states, wherein memory cells forming the same initial threshold voltage distribution constitute a subset; and
perform a reprogramming operation on the plurality of memory cells, wherein the reprogramming operation includes: verifying the memory cells in each subset respectively, to select a memory cell in each subset of which a threshold voltage is within a predetermined region in an initial threshold voltage distribution corresponding to the subset; and applying one or more preset program pulses to the selected memory cell in each subset; and
a memory controller coupled to the semiconductor device and configured to control the semiconductor device.

11. The memory system of claim 10, wherein predetermined regions in different initial threshold voltage distributions are the regions in the initial threshold voltage distributions in which the threshold voltages are smaller than the corresponding preset threshold voltages;
during the verification of the memory cells in each subset, the peripheral circuit is configured to:
apply a corresponding preset verify voltage related to a corresponding preset threshold voltage to the memory cells in the subset, and
select the memory cell that is turned on at the preset verify voltage.

12. The memory system of claim 11, wherein each of the initial threshold voltage distributions presents a normal distribution; and
ranges of the preset threshold voltages are less than or equal to μ−2σ, wherein μ is a mean value of the initial threshold voltage distribution, and σ is a standard deviation of the initial threshold voltage distribution.

13. The memory system of claim 10, wherein the reprogramming operation includes a plurality of program loops, each of the program loops comprises a verify operation and a programming operation followed to the verify operation;
during each of the program loops, the peripheral circuit is configured to:
verify the memory cells of the subset in the verify operation; and
apply a corresponding preset program pulse to the selected memory cell in the subset in the programming operation.

14. A programming method of a semiconductor device, the programming method comprising:
performing a programming operation on a plurality of memory cells coupled with a selected word line, such that threshold voltages of the plurality of memory cells form a plurality of initial threshold voltage distributions corresponding to a plurality of program states, wherein memory cells forming the same initial threshold voltage distribution constitute a subset; and
performing a reprogramming operation on the plurality of memory cells, wherein the reprogramming operation includes:
verifying the memory cells in each subset respectively, to select a memory cell in each subset of which a threshold voltage is within a predetermined region in an initial threshold voltage distribution corresponding to the subset; and
applying one or more corresponding preset program pulses to a selected memory cell in each subset.

15. The programming method of claim 14, wherein predetermined regions in different initial threshold voltage distributions are the regions in the initial threshold voltage distributions in which the threshold voltages are smaller than the corresponding preset threshold voltages;
the verifying the memory cells in each subset respectively includes: for the memory cells in each subset,
providing a corresponding preset verify voltage related to a corresponding preset threshold voltage to the memory cells in the subset, and selecting the memory cell that is not turned on at the preset verify voltage, wherein different subsets correspond to different preset verify voltages.

16. The programming method of claim 14, wherein the reprogramming operation includes a plurality of program loops, each of the program loops comprises a verify operation and a programming operation followed to the verify operation;
the performing the reprogramming operation on the plurality of memory cells includes:
performing the plurality of program loops in sequence, wherein during each of the program loops, the memory cells of one of the subsets are verified in the verify operation, and a corresponding preset program pulse is applied to the selected memory cell in the subset in the programming operation.

17. The programming method of claim 14, wherein the reprogramming operation includes: a verify stage and a program stage followed to the verify stage;
the performing the reprogramming operation on the plurality of memory cells includes:
verifying the memory cells in each subset respectively in the verify stage; and
applying a corresponding preset program pulse to the selected memory cell in each subset in the program stage.

18. The programming method of claim 17, wherein the apply a corresponding preset program pulse to the selected memory cell in each subset in the program stage includes:
applying a preset program pulse to the selected word line, wherein a falling edge of the preset program pulse includes multiple steps; and
providing allowed program voltages to bit lines coupled to each subset in sequence in a descending order of the initial threshold voltage distributions corresponding to the subsets, wherein when the preset program pulse reaches a maximum voltage, a bit line coupled to a selected memory cell in a subset corresponding to a highest threshold voltage distribution is applied with the allowed program voltage, and each time a voltage of the preset program pulse drops to a step, the allowed program voltage is correspondingly applied to the bit line coupled to the selected memory cell in one of the subsets.

19. The programming method of claim 14, wherein the performing the programming operation on the plurality of memory cells coupled to the selected word line includes:
performing a first programming operation on the plurality of memory cells, such that the threshold voltages of the plurality of memory cells form a plurality of intermediate distributions; and
performing a second programming operation on the plurality of memory cells, such that the plurality of intermediate distributions are changed to the plurality of initial threshold voltage distributions corresponding to the plurality of program states.

20. The programming method of claim 19, further comprising:
after the first programming operation is performed on the memory cell coupled to the selected word line and before the second programming operation and the reprogramming operation are successively performed, performing in sequence the second programming operation and the reprogramming operation on the memory cells coupled to a previous word line successively, and performing the first programming operation on the memory cells coupled to a next word line.
